(19) United States
(12) Patent Application Publication
(10) Pub. No.: US 2024/0090214 A1
(43) Pub. Date: Mar. 14, 2024

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventor: Jae Taek KIM, Icheon-si Gyeonggi-do (KR)

(73) Assignee: SK hynix Inc., Icheon-si Gyeonggi-do (KR)

(21) Appl. No.: 18/117,249

(22) Filed: Mar. 3, 2023

(30) Foreign Application Priority Data
Sep. 12, 2022 (KR) 10-2022-0115273

(51) Int. Cl. H10B 41/40; H10B 41/20; H10B 43/20; H10B 43/40; H10B 99/00

(52) U.S. Cl. CPC H10B 41/40; H10B 41/20; H10B 43/20; H10B 43/40; H10B 99/14

(57) ABSTRACT

Provided herein are a semiconductor memory device and a method of manufacturing the same. The semiconductor memory device includes a lower substrate, a peripheral circuit component located on the lower substrate, a lower bonding layer including a lower capacitor structure, the capacitor structure located on the peripheral circuit component, an upper bonding layer including an upper capacitor structure, the upper bonding layer bonded to the lower bonding layer, a plurality of cells and a dummy insulating layer that are located on the upper bonding layer, and an upper substrate being located on the plurality of cells and the dummy insulating layer, wherein the upper capacitor structure is coupled to the lower capacitor structure.

### CROSS-REFERENCE TO RELATED APPLICATION

The present application claims priority under 35 U.S.C. § 119(a) to Korean patent application number 10-2022-0115271, filed on Sep. 14, 2022, in the Korean Intellectual Property Office, the entire disclosure of which is incorporated herein by reference.

### BACKGROUND

### 1. Technical Field

Various embodiments of the present disclosure generally relate to a semiconductor memory device and a method of manufacturing the semiconductor memory device, and more particularly to a semiconductor memory device including a capacitor formed in a fine pattern in a dummy area, and a method of manufacturing the semiconductor memory device.

### 2. Related Art

Semiconductor memory devices may include a volatile memory device in which stored data is lost when power supply is interrupted, and a nonvolatile memory device in which stored data is retained even when power supply is interrupted.

Of the semiconductor memory devices, the nonvolatile memory device further requires the implementation of large capacity and high integration as the use of portable electronic devices, such as a mobile phone or a notebook computer increases.

Accordingly, as the structure of a two-dimensional (2D) nonvolatile memory device including memory cells formed in a single layer on a substrate is reaching its physical scaling limit (such as the degree of integration), a three-dimensional (3D) nonvolatile memory device including memory cells vertically stacked on a substrate has been proposed, and a scheme capable of forming more circuits in a limited chip area has been proposed.

### SUMMARY

An embodiment of the present disclosure may provide for a semiconductor memory device. The semiconductor memory device may include a first peripheral area and a second peripheral area, a lower substrate located in the first peripheral area and a second peripheral area, a peripheral circuit component located on the lower substrate, a lower bonding layer, including a lower capacitor structure, located on the peripheral circuit component in the second peripheral area, an upper bonding layer, including an upper capacitor structure, bonded to the lower bonding layer, a plurality of cells and a dummy insulating layer that are located on the upper bonding layer, and a cell area and a dummy area, an upper substrate located in the cell area and the dummy area, the upper substrate being located on the plurality of cells and the dummy insulating layer, wherein the upper capacitor structure is located in the dummy area and is coupled to the lower capacitor structure.

An embodiment of the present disclosure may provide for a method of manufacturing a semiconductor memory device. The method may include forming a peripheral circuit component on a lower substrate on which a first peripheral area and a second peripheral area are defined, forming a lower bonding layer, including a lower capacitor structure, located on the peripheral circuit component in the second peripheral area, forming a plurality of cells and a dummy insulating layer on an upper substrate on which a cell area and a dummy area are defined, wherein the dummy insulating layer is located in the dummy area and the plurality of cells are located in the cell area, forming an upper bonding layer, including an upper capacitor structure, on the dummy insulating layer in the dummy area, and bonding the lower bonding layer and the upper bonding layer to each other such that the lower capacitor structure and the upper capacitor structure are coupled to each other.

### BRIEF DESCRIPTION OF THE DRAWINGS

FIG. 1 is a diagram illustrating a semiconductor memory device according to an embodiment of the present disclosure.

FIG. 2 is a diagram illustrating the configuration of a memory block and a connection relationship between the memory block and peripheral circuits.

FIG. 3 is a diagram illustrating a structure according to an embodiment of the present disclosure.

FIGS. 4, 5, 6, 7, 8, 9, 10, and 11 are diagrams illustrating a method of manufacturing a lower structure according to an embodiment of the present disclosure.

FIGS. 12, 13, 14, 15, 16, 17, 18, and 19 are diagrams illustrating a method of manufacturing an upper structure according to an embodiment of the present disclosure.

FIGS. 20 and 21 are diagrams illustrating a method of bonding the lower structure and the upper structure to each other according to an embodiment of the present disclosure.

FIG. 22 is a diagram illustrating an embodiment of a memory system including a semiconductor memory device according to an embodiment of the present disclosure.

FIG. 23 is a diagram illustrating an embodiment of a memory system including a semiconductor memory device according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a semiconductor memory device and a method of manufacturing the semiconductor memory device, which more efficiently utilize the space of the semiconductor memory device and reduce the size of the semiconductor memory device by forming a capacitor in a fine pattern in a dummy area, thus implementing high integration of the semiconductor memory device and improving the reliability of the semiconductor memory device.

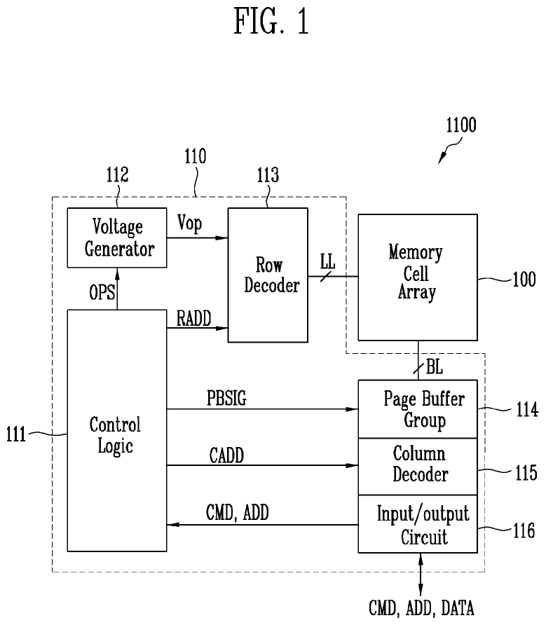

FIG. 1 is a diagram illustrating a semiconductor memory device according to an embodiment of the present disclosure.

Referring to FIG. 1, a semiconductor memory device 1100 may include a memory cell array 100 in which data may be stored and peripheral circuits 110, which may perform a program operation, a read operation, or an erase operation on the memory cell array 100.

The memory cell array 100 may include a plurality of memory blocks, each including nonvolatile memory cells. Local lines LL may be coupled to each of the memory blocks, and bit lines BL may be coupled in common to the memory blocks.

The peripheral circuits 110 may include a control logic 111, a voltage generator 112, a row decoder 113, a page buffer group 114, a column decoder 115, and an input/output circuit 116.

The control logic 111 may control the voltage generator 112, the row decoder 113, the page buffer group 114, the column decoder 115, and the input/output circuit 116 in response to a command CMD and an address ADD. For example, the control logic 111 may output an operation signal OPS and a page buffer control signal PBSIG in response to the command CMD and may output a row address RADD and a column address CADD in response to the address ADD.

The voltage generator 112 may generate and output operating voltages Vop that are required for a program operation, a read operation, or an erase operation in response to the operation signal OPS. For example, the voltage generator 112 may generate and output the operating voltages Vop, such as a program voltage, a read voltage, an erase voltage, and a pass voltage.

The row decoder 113 may transfer the operating voltages Vop to a selected memory block through the local lines LL in response to the row address RADD.

The page buffer group 114 may include a plurality of page buffers that are coupled to the bit lines BL. The page buffer group 114 may temporarily store data in response to the page buffer control signal PBSIG during a program operation or a read operation.

The column decoder 115 may transfer data between the page buffer group 114 and the input/output circuit 116 in response to the column address CADD.

The input/output circuit 116 may receive a command CMD and an address ADD from an external device and may transmit the command CMD the address ADD to the control logic 111. The input/output circuit 116 may transmit data DATA, received from the external device, to the column decoder 115 during a program operation and may output the data DATA, received from the column decoder 115, to the external device during a read operation.

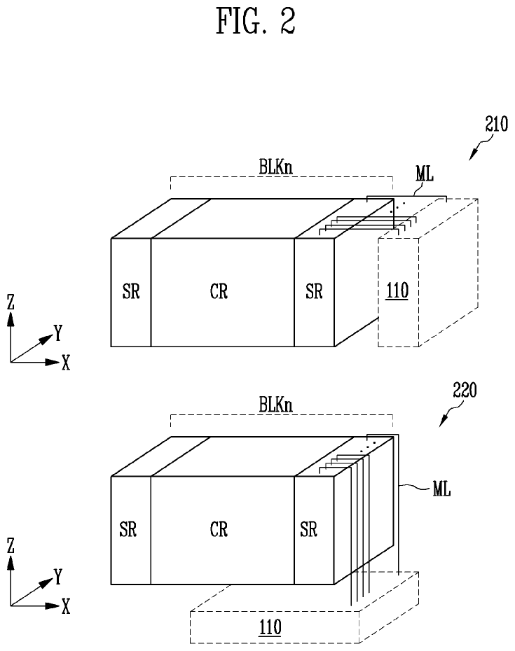

FIG. 2 is a diagram illustrating the configuration of a memory block and a connection relationship between the memory block and peripheral circuits.

Referring to FIG. 2, a memory block BLKn that is formed in a three-dimensional (3D) structure may include a cell region CR including memory cells and slimming regions SR for electrically connecting peripheral circuits 110 to the cell region CR. For example, the cell region CR may include a plurality of vertical strings in which memory cells and select transistors are stacked, and the slimming regions SR may include ends of a plurality of gate lines that are coupled to the memory cells and the select transistors. For example, in the slimming regions SR, gate lines may be stacked in a stepped structure and may be formed in a stepped structure in which a gate line that is located in a relatively low portion extends longer than a gate line that is located in a relatively high portion. The gate lines that are exposed through the stepped structure may be coupled to the peripheral circuits 110 through contact plugs.

When the peripheral circuits 110 are disposed in a direction (e.g., X direction) that is horizontal to the memory block BLKn (structure 210), a plurality of lines ML for electrically connecting the slimming regions SR to the peripheral circuits 110 may be formed. For example, in structure 210, the plurality of lines ML may be disposed to extend along the X direction and to be spaced apart from each other along a Y direction that is perpendicular to the X direction.

When the peripheral circuits 110 are disposed in a direction (e.g., Z direction) that is vertical to the memory block BLKn (structure 220), a plurality of lines ML for electrically connecting the slimming regions SR to the peripheral circuits 110 may be disposed to extend along the Z direction, which is perpendicular to both the X direction and the Y direction, and to be spaced apart from each other along the Y direction.

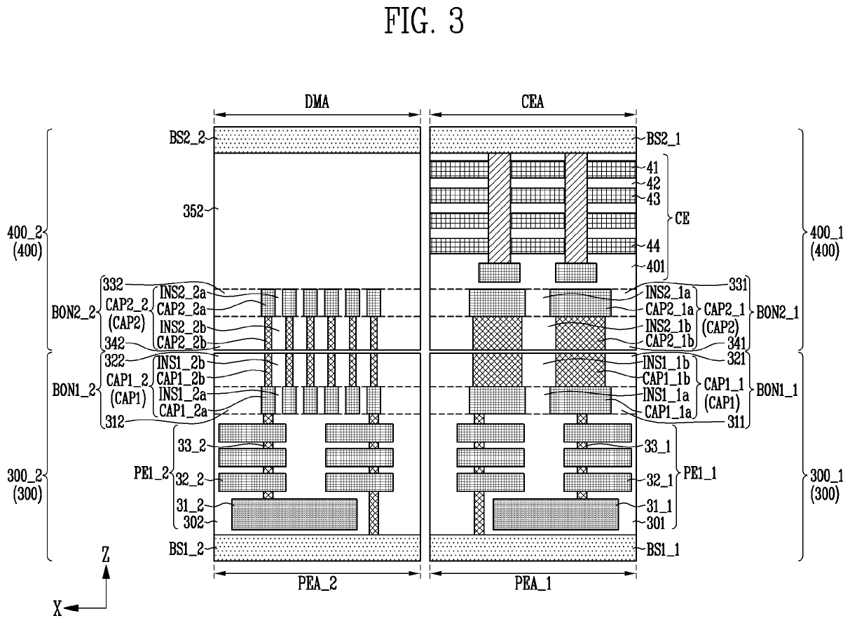

FIG. 3 is a diagram illustrating a structure according to an embodiment of the present disclosure.

Referring to FIG. 3, a semiconductor memory device according to an embodiment of the present disclosure may include a lower structure 300 including a lower capacitor/bonding structure CAP1 and an upper structure 400 including an upper capacitor/bonding structure CAP2. In an embodiment, the lower structure 300 may include peripheral circuit components PE1_1 and PE1_2, and the upper structure 400 may include a plurality of cells CE. The lower structure 300, according to an embodiment, may include a first peripheral area PEA_1 and a second peripheral area PEA_2 that are defined in one direction (e.g., X direction), and the upper structure 400 according to an embodiment may include a cell area CEA and a dummy area DMA that are defined in one direction (e.g., X direction).

The lower structure 300 according to an embodiment may include a first lower structure 300_1 that is formed in the first peripheral area PEA_1 and a second lower structure 300_2 that is formed in the second peripheral area PEA_2.

In the first peripheral area PEA_1, a first lower substrate BS1_1 may be provided. The first peripheral circuit component PE1_1 and a first lower bonding layer BON1_1 may be sequentially stacked on the first lower substrate BS1_1 in a direction (e.g., Z direction) that is vertical to the one direction, whereby the first lower structure 300_1 may be formed.

The first lower substrate BS1_1 may be a substrate including a semiconductor material, and the semiconductor material may be, for example, a material containing or including silicon.

The first peripheral circuit component PE1_1 may be, for example, a semiconductor substrate, or may include a structure corresponding to peripheral circuits formed on the semiconductor substrate. The first peripheral circuit component PE1_1 may be formed on the first lower substrate BS1_1 and may include a first insulating layer 301 and a plurality of first lower connection structures 31_1, 32_1, and 33_1.

The first insulating layer 301 may be formed on the first lower substrate BS1_1 in the first peripheral area PEA_1. The first insulating layer 301 may include a plurality of insulating layers (not illustrated) that are stacked. The first insulating layer 301 may be formed of silicon oxide containing a small amount of impurities or silicon oxide containing no impurities. The first insulating layer 301 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The first insulating layer 301 may be formed through a chemical deposition method by using heat or plasma or may be formed through various deposition methods including a spin-coating method.

The plurality of first lower connection structures 31_1, 32_1, and 33_1 may be formed in the first insulating layer 301 in the first peripheral area PEA_1. The plurality of first lower connection structures 31_1, 32_1, and 33_1 may be, for example, a material containing or including tungsten (W). The plurality of first lower connection structures 31_1, 32_1, and 33_1 may be formed on the first lower substrate BS1_1 and may be coupled to a lower bonding structure CAP1_1, which will be described later.

The first lower bonding layer BON1_1 may be formed on the first peripheral circuit component PE1_1 in the first peripheral area PEA_1 and may include the lower bonding structure CAP1_1, a third insulating layer 311, and a fifth insulating layer 321.

The lower bonding structure CAP1_1 may be formed on the first peripheral circuit component PE1_1 and may be coupled to the plurality of first lower connection structures 31_1, 32_1, and 33_1. Further, the lower bonding structure CAP1_1 may be coupled to a first upper bonding structure CAP2_1, which will be described later, when the first lower structure 300_1 is bonded to the first upper structure 400_1.

The lower bonding structure CAP1_1 may include first lower conductive patterns CAP1_1a and CAP1_1b that are arranged to be parallel to each other in one direction (e.g., X direction) and first lower insulating patterns INS1_1a and INS1_1b that are formed between the first lower conductive patterns CAP1_1a and CAP1_1b.

The first lower conductive patterns CAP1_1a and CAP1_1b may be formed in the third insulating layer 311 and the fifth insulating layer 321, respectively, in the first peripheral area PEA_1. The first lower conductive patterns CAP1_1a and CAP1_1b may be coupled to the plurality of first lower connection structures 31_1, 32_1, and 33_1. The first lower conductive patterns CAP1_1a and CAP1_1b may be formed of the same material as the plurality of first lower connection structures 31_1, 32_1, and 33_1 and may be made of, for example, a material containing or including tungsten (W).

The first lower insulating patterns INS1_1a and INS1_1b may be formed of silicon oxide containing a small amount of impurities or silicon oxide containing no impurities. The first lower insulating patterns INS1_1a and INS1_1b may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG).

The third insulating layer 311 and the fifth insulating layer 321 may be formed of the same material and may be formed through the same process. Also, the third insulating layer 311 and the fifth insulating layer 321 may be formed of the same material as the first insulating layer 301 and may be formed through the same process as the first insulating layer 301. The third insulating layer 311 and the fifth insulating layer 321 may be formed of silicon oxide containing a small amount of impurities or silicon oxide containing no impurities. The third insulating layer 311 and the fifth insulating layer 321 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The third insulating layer 311 and the fifth insulating layer 321 may be formed through a chemical deposition method by using heat or plasma or may be formed through various deposition methods including a spin coating method.

In the second peripheral area PEA_2, a second lower substrate BS1_2 may be provided. A second peripheral circuit component PE1_2 and a second lower bonding layer BON1_2 may be sequentially stacked on the second lower substrate BS1_2 in a direction (e.g., Z direction) that is vertical to the one direction, whereby the second lower structure 300_2 may be formed.

The second lower substrate BS1_2 may be the same substrate extending from the first lower substrate BS1_1. The second lower substrate BS1_2 may be a substrate including a semiconductor material, and the semiconductor material may be, for example, a material containing or including silicon.

The second peripheral circuit component PE1_2 and the first peripheral circuit component PE1_1 may be identical to each other and may be simultaneously formed on the same layer through the same process. The second peripheral circuit component PE1_2 may be, for example, a semiconductor substrate, or may include a structure corresponding to peripheral circuits that are formed on the semiconductor substrate. The second peripheral circuit component PE1_2 may be formed on the second lower substrate BS1_2 and may include a second insulating layer 302 and a plurality of second lower connection structures 31_2, 32_2, and 33_2.

The second insulating layer 302 and the first insulating layer 301 may be identical to each other and may be simultaneously formed on the same layer through the same process. The second insulating layer 302 may be formed on the second lower substrate BS1_2 in the second peripheral area PEA_2. The second insulating layer 302 may include a plurality of insulating layers (not illustrated) that are stacked. The second insulating layer 302 may be formed of silicon oxide containing a small amount of impurities or silicon oxide containing no impurities. The second insulating layer 302 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The second insulating layer 302 may be formed through a chemical deposition method by using heat or plasma or may be formed through various deposition methods including a spin-coating method.

The plurality of second lower connection structures 31_2, 32_2, and 33_2 and the plurality of first lower connection structures 31_1, 32_1, and 33_1 may be identical to each other and may be simultaneously formed on the same layer through the same process. The plurality of second lower connection structures 31_2, 32_2, and 33_2 may be formed in the second insulating layer 302 in the second peripheral area PEA_2. Further, the plurality of second lower connection structures 31_2, 32_2, and 33_2 may be made of, for example, a material containing or including tungsten (W). The plurality of second lower connection structures 31_2, 32_2, and 33_2 may be formed on the second lower substrate BS1_2 and may be coupled to a lower capacitor structure CAP1_2, which will be described later.

The second lower bonding layer BON1_2 may be formed on the second peripheral circuit component PE1_2 in the second peripheral area PEA_2 and may include the lower capacitor structure CAP1_2, a fourth insulating layer 312, and a sixth insulating layer 322.

The lower capacitor structure CAP1_2 and the lower bonding structure CAP1_1 may include the same material and may be simultaneously formed on the same layer through the same process. The lower capacitor structure CAP1_2 may be formed on the second peripheral circuit component PE1_2 and may be coupled to the plurality of second lower connection structures 31_2, 32_2, and 33_2. Further, when the second lower structure 300_2 and the second upper structure 400_2 are bonded to each other, the lower capacitor structure CAP1_2 may be coupled to a second upper bonding structure CAP2_2, which will be described later.

The lower capacitor structure CAP1_2 may include second lower conductive patterns CAP1_2a and CAP1_2b that are arranged to be parallel to each other in one direction (e.g., X direction) and second lower insulating patterns INS1_2a and INS1_2b that are formed between the second lower conductive patterns CAP1_2a and CAP1_2b.

The second lower conductive patterns CAP1_2a and CAP1_2b and the first lower conductive patterns CAP1_1a and CAP1_1b may include the same material and may be simultaneously formed on the same layer through the same process. The second lower conductive patterns CAP1_2a and CAP1_2b may be formed in the fourth insulating layer 312 and the sixth insulating layer 322, respectively, in the second peripheral area PEA_2. The second lower conductive patterns CAP1_2a and CAP1_2b may be coupled to the plurality of second lower connection structures 31_2, 32_2, and 33_2. The second lower conductive patterns CAP1_2a and CAP1_2b may be formed of the same material as the plurality of first lower connection structures 31_2, 32_2, and 33_2 and may be formed of, for example, a material containing or including tungsten (W).

The second lower insulating patterns INS1_2a and INS1_2b and the first lower insulating patterns INS1_1a and INS1_1b may include the same material and may be simultaneously formed on the same layer through the same process. The second lower insulating patterns INS1_2a and INS1_2b may be formed of silicon oxide containing a small amount of impurities or silicon oxide containing no impurities. The second lower insulating patterns INS1_2a and INS1_2b may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG).

The fourth insulating layer 312 and the sixth insulating layer 322 may include the same materials as the third insulating layer 311 and the fifth insulating layer 321, respectively, and may be formed simultaneously therewith on the same layer through the same process. Furthermore, the fourth insulating layer 312 and the sixth insulating layer 322 may be formed of the same material and may be formed through the same process. Also, the fourth insulating layer 312 and the sixth insulating layer 322 may be formed of the same material as the second insulating layer 302 and may be formed through the same process as the second insulating layer 302. The fourth insulating layer 312 and the sixth insulating layer 322 may be formed of silicon oxide containing a small amount of impurities or silicon oxide containing no impurities. The fourth insulating layer 312 and the sixth insulating layer 322 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The fourth insulating layer 312 and the sixth insulating layer 322 may be formed through a chemical deposition method by using heat or plasma or may be formed through various deposition methods including a spin coating method.

The upper structure 400 may be formed on the lower structure 300, and the upper structure 400, according to an embodiment, may include a first upper structure 400_1 that is formed in the cell area CEA and a second upper structure 400_2 that is formed in the dummy area DMA.

In the cell area CEA, a plurality of cells CE and a first upper substrate BS2_1 may be sequentially stacked on a first upper bonding layer BON2_1 in a direction (e.g., Z direction) that is vertical to one direction, whereby the first upper structure 400_1 may be formed. The first upper structure 400_1 may be formed on the first lower structure 300_1. Also, in an embodiment, the first upper structure 400_1 may be formed such that the plurality of cells CE and the first upper bonding layer BON2_1 are sequentially formed on the first upper substrate BS2_1 in the direction (e.g., Z direction) that is vertical to the one direction. Further, in an embodiment, the first upper structure 400_1 may be formed such that the first upper bonding layer BON2_1 contacts the first lower structure 300_1.

The first upper bonding layer BON2_1 may be formed on the first lower structure 300_1 to contact the first lower structure 300_1 and may include an upper bonding structure CAP2_1, a seventh insulating layer 331, and a ninth insulating layer 341.

The upper bonding structure CAP2_1 and the lower bonding structure CAP1_1 may include the same material and may be formed through the same process. The upper bonding structure CAP2_1 may be formed on the first lower structure 300_1 and may be coupled to the lower bonding structure CAP1_1.

The upper bonding structure CAP2_1 may include first upper conductive patterns CAP2_1a and CAP2_1b that are arranged to be parallel to each other in one direction (e.g., X direction), and first upper insulating patterns INS2_1a and INS2_1b that are formed between the first upper conductive patterns CAP2_1a and CAP2_1b.

The first upper conductive patterns CAP2_1a and CAP2_1b and the first lower conductive patterns CAP1_1a and CAP1_1b may include the same material and may be formed through the same process.

The first upper conductive patterns CAP2_1a and CAP2_1b may be formed in the seventh insulating layer 331 and the ninth insulating layer 341, respectively, in the cell area CEA. The first upper conductive patterns CAP2_1a and CAP2_1b may be coupled to the first lower conductive patterns CAP1_1a and CAP1_1b. The first upper conductive patterns CAP2_1a and CAP2_1b may be formed of, for example, a material containing or including tungsten (W).

The first upper insulating patterns INS2_1a and INS2_1b and the first lower insulating patterns INS1_1a and INS1_1b may include the same material and may be formed through the same process. The first upper insulating patterns INS2_1a and INS2_1b may be formed of silicon oxide containing a small amount of impurities or silicon oxide containing no impurities. The first upper insulating patterns INS2_1a and INS2_1b may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG).

The seventh insulating layer 331 and the ninth insulating layer 341 may include the same materials as the third insulating layer 311 and the fifth insulating layer 321, respectively, and may be formed through the same process. The seventh insulating layer 331 and the ninth insulating layer 341 may be formed of the same material and may be formed through the same process. The seventh insulating layer 331 and the ninth insulating layer 341 may be formed of silicon oxide containing a small amount of impurities or silicon oxide containing no impurities. The seventh insulating layer 331 and the ninth insulating layer 341 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The seventh insulating layer 331 and the ninth insulating layer 341 may be formed through a chemical deposition method using heat or plasma or may be formed through various deposition methods including a spin coating method.

The plurality of cells CE may include a plurality of insulating layers 42 and a plurality of gate layers 41, 43, and 44 that are alternately stacked on the first upper bonding layer BON2_1. Each of the plurality of insulating layers 42 may be formed of, for example, an oxide layer, and each of the plurality of gate layers 41, 43, and 44 may be formed of a layer including at least one of tungsten (W), cobalt (Co), nickel (Ni), molybdenum (Mo), silicon (si), and polysilicon (poly-Si).

The plurality of gate layers 41, 43, and 44 may be used as word lines or selection lines in a memory block and may include a source selection line 41, a word line 43, and a drain selection line 44. According to an embodiment, the source selection line 41 may be located in an uppermost portion, among the plurality of gates layers 41, 43, and 44, and the drain selection line 44 may be located in a lowermost portion, among the plurality of gate layers 41, 43, and 44.

The first upper substrate BS2_1 may be provided on the plurality of cells CE in the cell area CEA. The first upper substrate BS2_1 may be identical to the first lower substrate BS1_1. The first upper substrate BS2_1 may be a substrate including a semiconductor material, and the semiconductor material may be, for example, a material containing or including silicon.

In the dummy area DMA, an eleventh insulating layer 352 (i.e., a dummy insulating layer) and a second upper substrate BS2_2 may be sequentially stacked on a second upper bonding layer BON2_2 in the direction (e.g., Z direction) that is vertical to one direction, whereby the second upper structure 400_2 may be formed. The second upper structure 400_2 may be formed on the second lower structure 300_2. Further, in an embodiment, the second upper structure 400_2 may be formed such that the eleventh insulating layer 352 and the second upper bonding layer BON2_2 are sequentially stacked on the second upper substrate BS2_2 in the direction (e.g., Z direction) that is vertical to the one direction, and thereafter the second upper bonding layer BON2_2 is disposed to contact the second lower structure 300_2.

The second upper bonding layer BON2_2 may be formed on the second lower structure 300_2 to contact the second lower structure 300_2 and may include an upper capacitor structure CAP2_2, an eighth insulating layer 332, and a tenth insulating layer 342.

The upper capacitor structure CAP2_2 and the upper bonding structure CAP2_1 may include the same material and may be simultaneously formed through the same process. Furthermore, the upper capacitor structure CAP2_2 and the lower capacitor structure CAP1_2 may include the same material and may be formed through the same process. The upper capacitor structure CAP2_2 may be formed on the second lower structure 300_2 and may be coupled to the lower capacitor structure CAP1_2.

The upper capacitor structure CAP2_2 may include second upper conductive patterns CAP2_2a and CAP2_2b that are arranged to be parallel to each other in one direction (e.g., X direction), and second upper insulating patterns INS2_2a and INS2_2b that are formed between the second upper conductive patterns CAP2_2a and CAP2_2b.

The second upper conductive patterns CAP2_2a and CAP2_2b and the first upper conductive patterns CAP2_1a and CAP2_1b may include the same material and may be simultaneously formed through the same process. Further, the second upper conductive patterns CAP2_2a and CAP2_2b and the second lower conductive patterns CAP1_2a and CAP1_2b may include the same material and may be formed through the same process. The second upper conductive patterns CAP2_2a and CAP2_2b may be formed in the eighth insulating layer 332 and the tenth insulating layer 342, respectively, in the dummy area DMA. The second upper conductive patterns CAP2_2a and CAP2_2b may be coupled to the second lower conductive patterns CAP1_2a and CAP1_2b. The second upper conductive patterns CAP2_2a and CAP2_2b may be formed of, for example, a material containing or including tungsten (W).

The second upper insulating patterns INS2_2a and INS2_2b and the first upper insulating patterns INS2_1a and INS2_1b may include the same material and may be simultaneously formed through the same process. Also, the second upper insulating patterns INS2_2a and INS2_2b and the second lower insulating patterns INS1_2a and INS1_2b may include the same material and may be formed through the same process. The second upper insulating patterns INS2_2a and INS2_2b may be formed of silicon oxide containing a small amount of impurities or silicon oxide containing no impurities. The second upper insulating patterns INS2_2a and INS2_2b may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG).

The eighth and tenth insulating layers 332 and 342 may include the same materials as the seventh and ninth insulating layers 331 and 341, respectively, and may be formed simultaneously therewith through the same process. Furthermore, the eighth and tenth insulating layers 332 and 342 may include the same materials as the fourth and sixth insulating layers 312 and 322, respectively, and may be formed through the same process. The eighth insulating layer 332 and the tenth insulating layer 342 may be formed of the same material and may be formed through the same process. The eighth insulating layer 332 and the tenth insulating layer 342 may be formed of silicon oxide containing a small amount of impurities or silicon oxide containing no impurities. The eighth insulating layer 332 and the tenth insulating layer 342 may be made of a material corresponding to at least one of boron silicate glass (BSG), phosphorous silicate glass (PSG), boron phosphorous silicate glass (BPSG), silicon oxy fluoride (SiOF), silicon carbonic hydro oxide (SiCHO), tetraethyl orthosilicate (TEOS), and undoped silicate glass (USG). The eighth insulating layer 332 and the tenth insulating layer 342 may be formed through a chemical deposition method using heat or plasma or may be formed through various deposition methods including a spin coating method.

The eleventh insulating layer 352 may be formed on the second upper bonding layer BON2_2. The eleventh insulating layer 352 may be formed of the same material as the plurality of insulating layers 42 and may be formed of, for example, an oxide layer.

The second upper substrate BS2_2 may be provided on the eleventh insulating layer 352 in the dummy area DMA. The second upper substrate BS2_2 may be the same substrate extending from the first upper substrate BS2_1. Also, the second upper substrate BS2_2 may be identical to the second lower substrate BS1_2. The second upper substrate BS2_2 may be a substrate including a semiconductor material, and the semiconductor material may be, for example, a material containing or including silicon.

The upper capacitor structure CAP2_2 may be formed in the dummy area DMA and may be coupled to the lower capacitor structure CAP1_2, and thus, the space of the semiconductor memory device may be more efficiently utilized, and the size of the semiconductor memory device may be reduced. Accordingly, a semiconductor device which is highly integrated and has improved reliability can be provided. Furthermore, because the upper capacitor structure CAP2_2 and the upper bonding structure CAP2_1 may be simultaneously formed through the same process, an additional process is not required, and thus, a manufacturing process may be simplified.

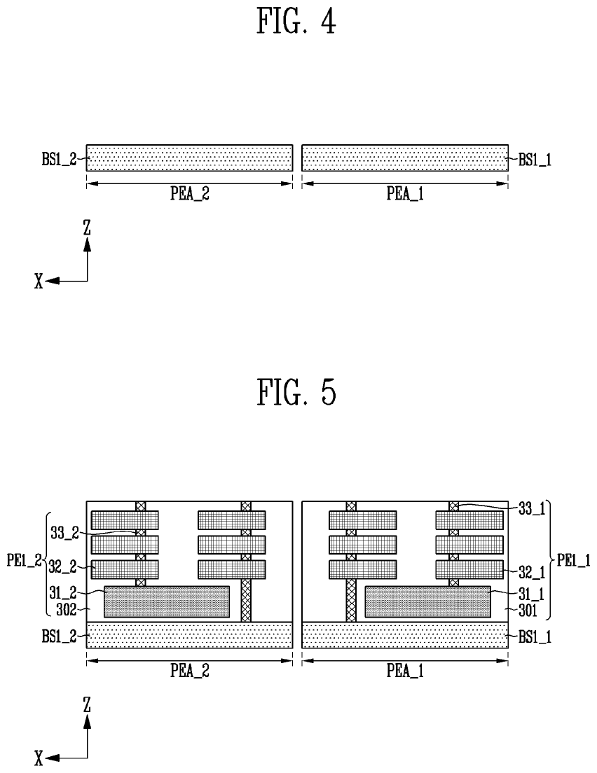

FIGS. 4, 5, 6, 7, 8, 9, 10, and 11 are diagrams illustrating a method of manufacturing a lower structure 300 according to an embodiment of the present disclosure.

Referring to FIG. 4, a first peripheral area PEA_1 and a second peripheral area PEA_2 may be separated from each other along a first direction (e.g., X direction). In the first peripheral area PEA_1, a first lower substrate BS1_1 may be provided. Furthermore, in the second peripheral area PEA_2, a second lower substrate BS1_2 that is the same substrate extending from the first lower substrate BS1_1 may be provided.

Referring to FIG. 5, a first peripheral circuit component PE1_1 may be formed on the first lower substrate BS1_1 in the first peripheral area PEA_1, and a second peripheral circuit component PE1_2 may be formed on the second lower substrate BS1_2 in the second peripheral area PEA_2. The first peripheral circuit component PE1_1 and the second peripheral circuit component PE1_2 may be simultaneously formed through the same process.

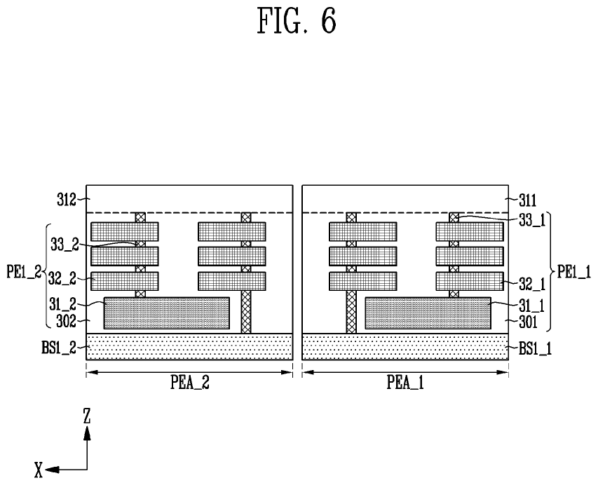

Referring to FIG. 6, a third insulating layer 311 may be formed on the first peripheral circuit component PE1_1, and a fourth insulating layer 312 may be formed on the second peripheral circuit component PE1_2. The third insulating layer 311 and the fourth insulating layer 312 may be simultaneously formed through the same process.

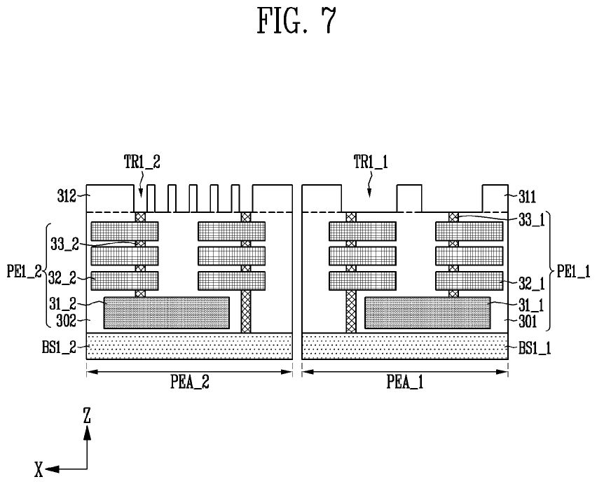

Referring to FIG. 7, a first trench TR1_1 may be formed in the third insulating layer 311. For example, the first trench TR1_1 may be formed by etching a portion of the third insulating layer 311. The first trench TR1_1 may be formed in such a way that a mask pattern (not illustrated) having an opening that is formed therein is formed on the third insulating layer 311, and the third insulating layer 311 that is exposed through the opening is etched. An etching process may be performed until some of a plurality of first lower connection structures 31_1, 32_1, and 33_1 of the first peripheral circuit component PE1_1 are exposed. Accordingly, the first trench TR1_1 may be formed at the same height as the third insulating layer 311.

A second trench TR1_2 may be formed in the fourth insulating layer 312. The second trench TR1_2 and the first trench TR1_1 may be simultaneously formed through the same process. For example, the first trench TR1_1 and the second trench TR1_2 may be simultaneously formed by etching a portion of the fourth insulating layer 312 when etching a portion of the third insulating layer 311. The second trench TR1_2 may be formed in such a way that a mask pattern (not illustrated) having an opening that is formed therein is formed on the fourth insulating layer 312, and the fourth insulating layer 312 that is exposed through the opening is etched. An etching process may be performed until some of a plurality of second lower connection structures 31_2, 32_2, and 33_2 of the second peripheral circuit component PE1_2 are exposed. Accordingly, the second trench TR1_2 may be formed at the same height as the fourth insulating layer 312.

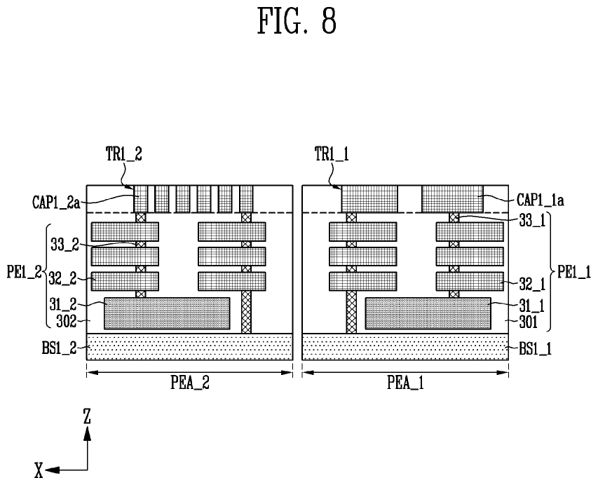

Referring to FIG. 8, the first trench TR1_1 may be filled with material layers, and thus, a 1_1-th lower conductive pattern CAP1_1a may be formed. The material layers that are formed in the first trench TR1_1 may be formed of the same material as the plurality of first lower connection structures 31_1, 32_1, and 33_1. The material layers that are formed in the first trench TR1_1 may be formed of, for example, a material containing or including tungsten (W).

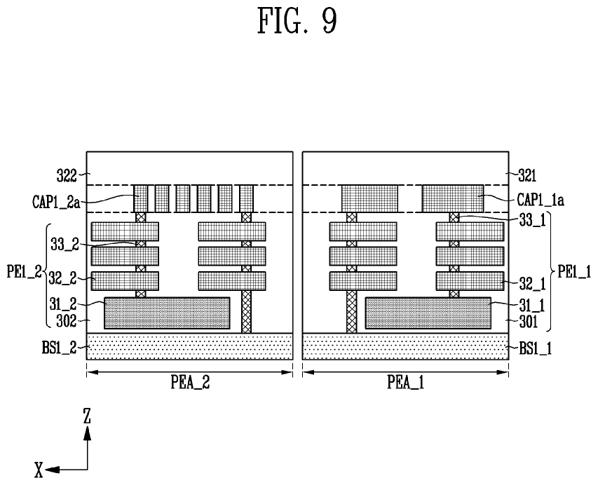

The second trench TR1_2 may be filled with material layers, and thus, a 2_1-th lower conductive pattern CAP1_2a may be formed. The 2_1-th lower conductive pattern CAP1_2a and the 1_1-th lower conductive pattern CAP1_1a may be simultaneously formed through the same process. For example, a process of filling the second trench TR1_2 with material layers may be performed simultaneously with a process of filling the first trench TR1_1 with material layers through the same process. At the same time that the first trench TR1_1 is filled with material layers, the second trench TR1_2 may also be filled with material layers. Accordingly, the material layers that are formed in the second trench TR1_2 may be identical to the material layers that are formed in the first trench TR1_1. Also, the material layers that are formed in the second trench TR1_2 may be made of the same material as the plurality of second lower connection structures 31_2, 32_2, and 33_2. The material layers that are formed in the second trench TR1_2 may be formed of, for example, a material containing or including tungsten (W). Referring to FIG. 9, a fifth insulating layer 321 may be formed on the third insulating layer 311 in which the 1_1-th lower conductive pattern CAP1_1a is formed, and a sixth insulating layer 322 may be formed on the fourth insulating layer 312 in which the 2_1-th lower conductive pattern CAP1_2a is formed. The fifth insulating layer 321 and the sixth insulating layer 322 may be simultaneously formed through the same process.

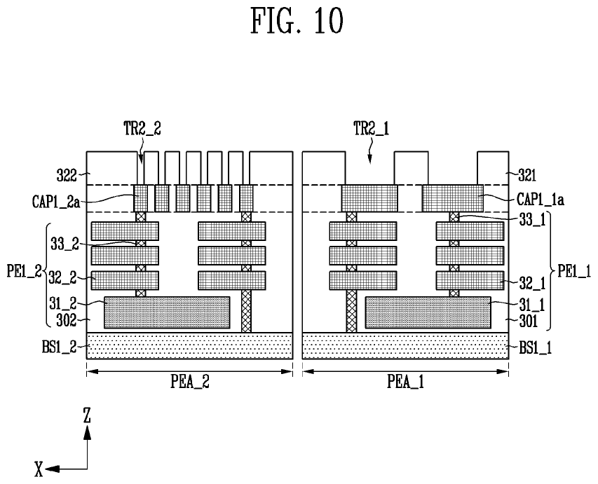

Referring to FIG. 10, a third trench TR2_1 may be formed in the fifth insulating layer 321. For example, the third trench TR2_1 may be formed by etching a portion of the fifth insulating layer 321. The third trench TR2_1 may be formed in such a way that a mask pattern (not illustrated) having an opening formed therein is formed on the fifth insulating layer 321, and the fifth insulating layer 321 that is exposed through the opening is etched. An etching process may be performed until a portion of the 1_1-th lower conductive pattern CAP1_1a is exposed. Accordingly, the third trench TR2_1 may be formed at the same height as the fifth insulating layer 321.

A fourth trench TR2_2 may be formed in the sixth insulating layer 322. The fourth trench TR2_2 and the third trench TR2_1 may be simultaneously formed through the same process. For example, the third trench TR2_1 and the fourth trench TR2_2 may be simultaneously formed by etching a portion of the sixth insulating layer 322 when etching a portion of the fifth insulating layer 321. The fourth trench TR2_2 may be formed in such a way that a mask pattern (not illustrated) having an opening formed therein is formed on the sixth insulating layer 322, and the sixth insulating layer 322 that is exposed through the opening is etched. An etching process may be performed until a portion of the 2_1-th lower conductive pattern CAP1_2a is exposed. Accordingly, the fourth trench TR2_2 may be formed at the same height as the sixth insulating layer 322.

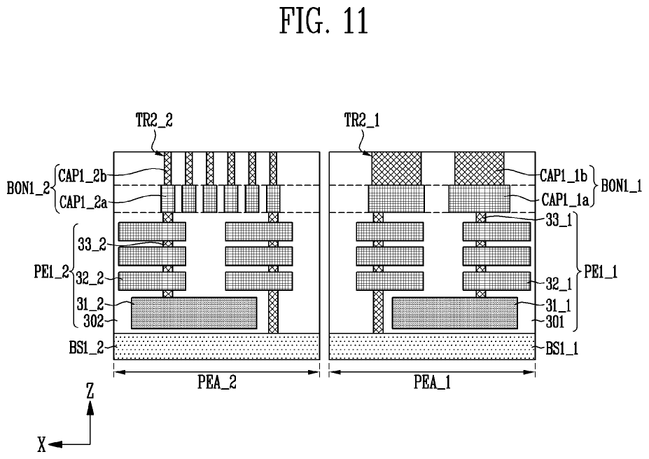

Referring to FIG. 11, the third trench TR2_1 may be filled with material layers, and thus, a 1_2-th lower conductive pattern CAP1_1b may be formed. The material layers that are formed in the third trench TR2_1 may be formed of the same material as the 1_1-th lower conductive pattern CAP1_1a. Further, the material layers that are formed in the third trench TR2_1 may be formed of the same material as the plurality of first lower connection structures 31_1, 32_1, and 33_1. The material layers that are formed in the third trench TR2_1 may be formed of, for example, a material containing or including tungsten (W).

The fourth trench TR2_2 may be filled with material layers, and thus, a 2_2-th lower conductive pattern CAP1_2b may be formed. The 2_2-th lower conductive pattern CAP1_2b and the 1_2-th lower conductive pattern CAP1_1b may be simultaneously formed through the same process. For example, a process of filling the fourth trench TR2_2 with material layers may be performed simultaneously with a process of filling the third trench TR2_1 with material layers through the same process. At the same time that the third trench TR2_1 is filled with material layers, the fourth trench TR2_2 may also be filled with material layers. Accordingly, the material layers that are formed in the fourth trench TR2_2 may be identical to the material layers that are formed in the third trench TR2_1. Furthermore, the material layers that are formed in the fourth trench TR2_2 may be made of the same material as the 2_1-th lower conductive pattern CAP1_2a and may be formed of the same material as the plurality of second lower connection structures 31_2, 32_2, and 33_2. The material layers that are formed in the fourth trench TR2_2 may be formed of, for example, a material containing or including tungsten (W).

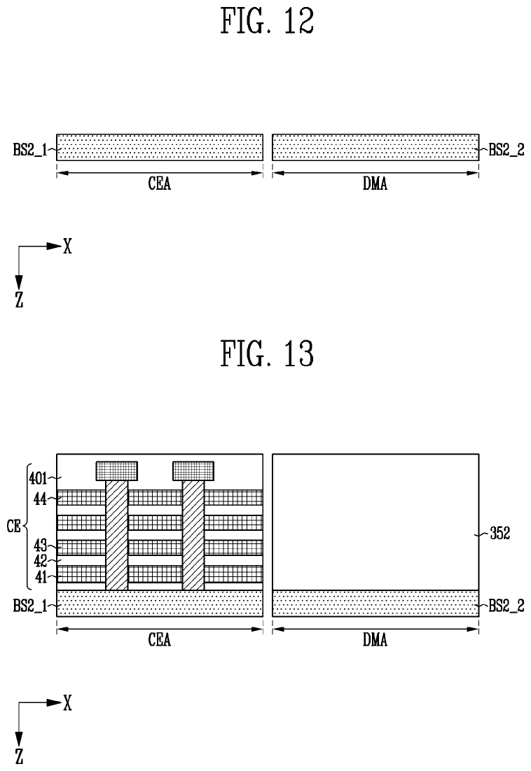

FIGS. 12, 13, 14, 15, 16, 17, 18, and 19 are diagrams illustrating a method of manufacturing an upper structure 400 according to an embodiment of the present disclosure.

Referring to FIG. 12, a cell area CEA and a dummy area DMA may be separated from each other along a first direction (e.g., X direction). In the cell area CEA, a first upper substrate BS2_1 may be provided, and in the dummy area DMA, a second upper substrate BS2_2 that is the same substrate extending from the first upper substrate BS2_1 may be provided.

Referring to FIG. 13, a plurality of cells CE may be formed on the first upper substrate BS2_1 in the cell area CEA, and an eleventh insulating layer 352 may be formed on the second upper substrate BS2_2 in the dummy area DMA.

The plurality of cells CE may include a plurality of insulating layers 42 and a plurality of gate layers 41, 43, and 44, which are alternately stacked, and a twelfth insulating layer 401. The plurality of gate layers 41, 43, and 44 may be used to form gate electrodes, such as for memory cells or select transistors, and the plurality of insulating layers 42 may be used to isolate the gate electrodes from each other. The plurality of gate layers 41, 43, and 44 may include, for example, a source selection line 41, a word line 43, and a drain selection line 44. In an embodiment, the source selection line 41 may be formed in a lowermost portion among the plurality of gate layers 41, 43, and 44, the drain selection line 44 may be formed in an uppermost portion among the plurality of gate layers 41, 43, and 44, and the word line 43 may be formed between the source selection line 41 and the drain selection line 44. The twelfth insulating layer 401 may be formed on the top of the plurality of insulating layers 42 and the plurality gate layers 41, 43, and 44, which are alternately stacked.

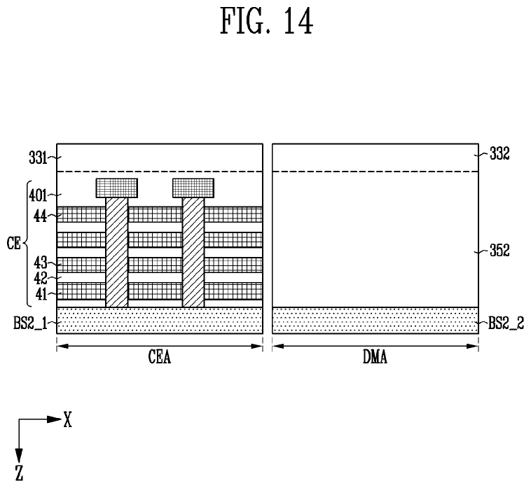

Referring to FIG. 14, a seventh insulating layer 331 may be formed on the plurality of cells CE, and an eighth insulating layer 332 may be formed on the eleventh insulating layer 352. The seventh insulating layer 331 and the eighth insulating layer 332 may be simultaneously formed through the same process.

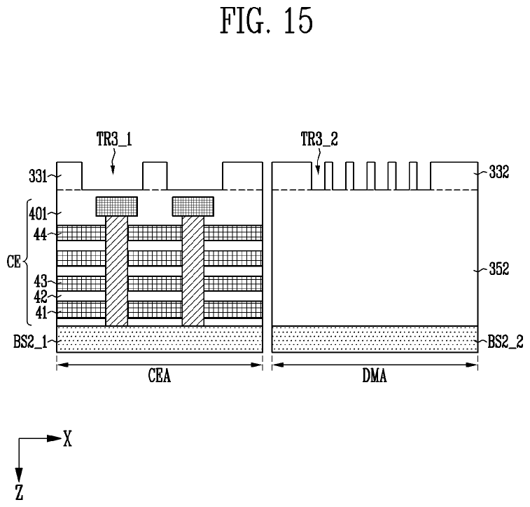

Referring to FIG. 15, a fifth trench TR3_1 may be formed in the ninth insulating layer 331. For example, the fifth trench TR3_1 may be formed by etching a portion of the seventh insulating layer 331. The fifth trench TR3_1 may be formed in such a way that a mask pattern (not illustrated) having an opening formed therein is formed on the seventh insulating layer 331, and the seventh insulating layer 331 that is exposed through the opening is etched. An etching process may be performed until a portion of the twelfth insulating layer 401 of the plurality of cells CE is exposed. Accordingly, the fifth trench TR3_1 may be formed at the same height as the seventh insulating layer 331.

A sixth trench TR3_2 may be formed in the eighth insulating layer 332. The sixth trench TR3_2 and the fifth trench TR3_1 may be simultaneously formed through the same process. For example, the fifth trench TR3_1 and the sixth trench TR3_2 may be simultaneously formed by etching a portion of the eighth insulating layer 332 when etching a portion of the seventh insulating layer 331. The sixth trench TR3_2 may be formed in such a way that a mask pattern (not illustrated) having an opening formed therein is formed on the eighth insulating layer 332, and the eighth insulating layer 332 that is exposed through the opening is etched. An etching process may be performed until a portion of the eleventh insulating layer 352 is exposed. Accordingly, the sixth trench TR3_2 may be formed at the same height as the eighth insulating layer 332.

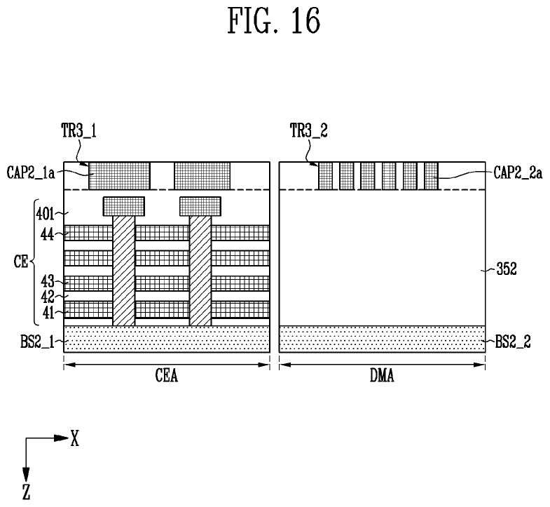

Referring to FIG. 16, the fifth trench TR3_1 may be filled with material layers, and thus, a 1_1-th upper conductive pattern CAP2_1a may be formed. The material layers that are formed in the fifth trench TR3_1 may be formed of the same material as the 1_1-th lower conductive pattern CAP1_1a. The material layers that are formed in the fifth trench TR3_1 may be formed of, for example, a material containing or including tungsten (W).

The sixth trench TR3_2 may be filled with material layers, and thus, a 2_1-th upper conductive pattern CAP1_2a may be formed. The 2_1-th upper conductive pattern CAP2_2a and the 1_1-th upper conductive pattern CAP2_1a may be simultaneously formed through the same process. For example, a process of filling the sixth trench TR3_2 with material layers may be performed simultaneously with a process of filling the fifth trench TR3_1 with material layers through the same process. At the same time that the fifth trench TR3_1 is filled with material layers, the sixth trench TR3_2 may also be filled with material layers. Accordingly, the material layers that are formed in the sixth trench TR3_2 may be identical to the material layers that are formed in the fifth trench TR3_1. Further, the material layers that are formed in the sixth trench TR3_2 may be formed of the same material as the 2_1-th lower conductive pattern CAP1_2a. The material layers that are formed in the sixth trench TR3_2 may be formed of, for example, a material containing or including tungsten (W).

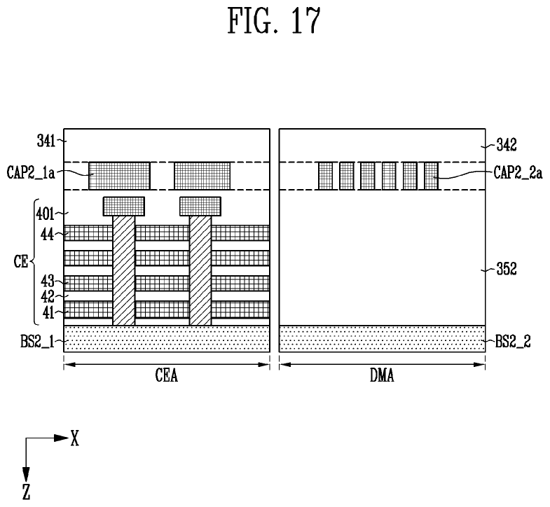

Referring to FIG. 17, a ninth insulating layer 341 may be formed on the seventh insulating layer 331 in which the 1_1-th upper conductive pattern CAP2_1a may be formed, and a tenth insulating layer 342 may be formed on the eighth insulating layer 332 in which the 2_1-th upper conductive pattern CAP2_2a is formed. The ninth insulating layer 341 and the tenth insulating layer 342 may be simultaneously formed through the same process.

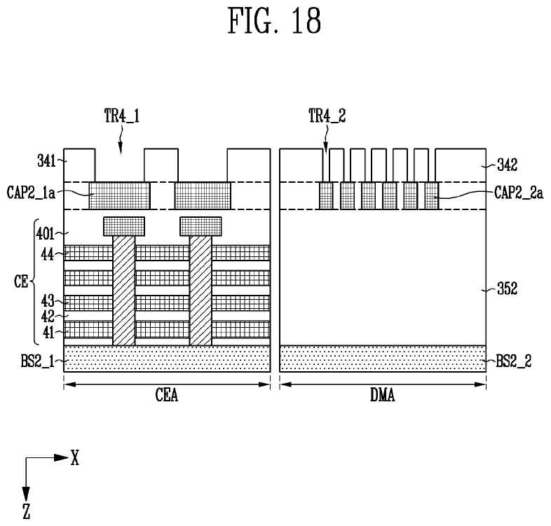

Referring to FIG. 18, a seventh trench TR4_1 may be formed in the ninth insulating layer 341. For example, the seventh trench TR4_1 may be formed by etching a portion of the ninth insulating layer 341. The seventh trench TR4_1 may be formed in such a way that a mask pattern (not illustrated) having an opening formed therein is formed on the ninth insulating layer 341, and the ninth insulating layer 341 that is exposed through the opening is etched. An etching process may be performed until a portion of the 1_1-th upper conductive pattern CAP2_1a is exposed. Accordingly, the seventh trench TR4_1 may be formed at the same height as the ninth insulating layer 341.

An eighth trench TR4_2 may be formed in the tenth insulating layer 342. The eighth trench TR4_2 and the seventh trench TR4_1 may be simultaneously formed through the same process. For example, the seventh trench TR4_1 and the eighth trench TR4_2 may be simultaneously formed by etching a portion of the tenth insulating layer 342 when etching a portion of the ninth insulating layer 341. The eighth trench TR4_2 may be formed in such a way that a mask pattern (not illustrated) having an opening formed therein is formed on the tenth insulating layer 342, and the tenth insulating layer 342 that is exposed through the opening is etched. An etching process may be performed until a portion of the 2_1-th upper conductive pattern CAP2_2a is exposed. Accordingly, the eighth trench TR4_2 may be formed at the same height as the tenth insulating layer 342.

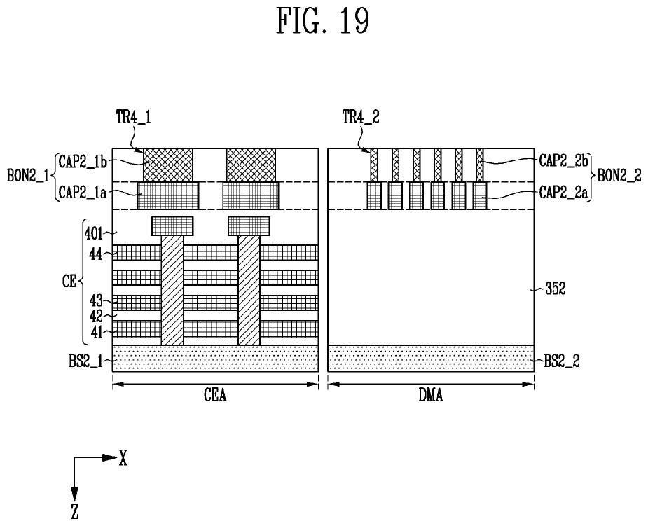

Referring to FIG. 19, the seventh trench TR4_1 may be filled with material layers, and thus, a 1_2-th upper conductive pattern CAP2_1b may be formed. The material layers that are formed in the seventh trench TR4_1 may be formed of the same material as the 1_1-th upper conductive pattern CAP2_1a. The material layers that are formed in the seventh trench TR4_1 may be formed of, for example, a material containing or including tungsten (W).

The eighth trench TR4_2 may be filled with material layers, and thus, a 2_2-th upper conductive pattern CAP2_2b may be formed. The 2_2-th upper conductive pattern CAP2_2b and the 1_2-th upper conductive pattern CAP2_1b may be simultaneously formed through the same process. For example, a process of filling the eighth trench TR4_2 with material layers may be performed simultaneously with a process of filling the seventh trench TR4_1 with material layers through the same process. At the same time that the seventh trench TR4_1 is filled with material layers, the eighth trench TR4_2 may also be filled with material layers. Accordingly, the material layers that are formed in the eighth trench TR4_2 may be identical to the material layers that are formed in the seventh trench TR4_1. Further, the material layers that are formed in the eighth trench TR4_2 may be formed of the same material as the 2_1-th upper conductive pattern CAP2_2a. The material layers that are formed in the eighth trench TR4_2 may be formed of, for example, a material containing or including tungsten (W).

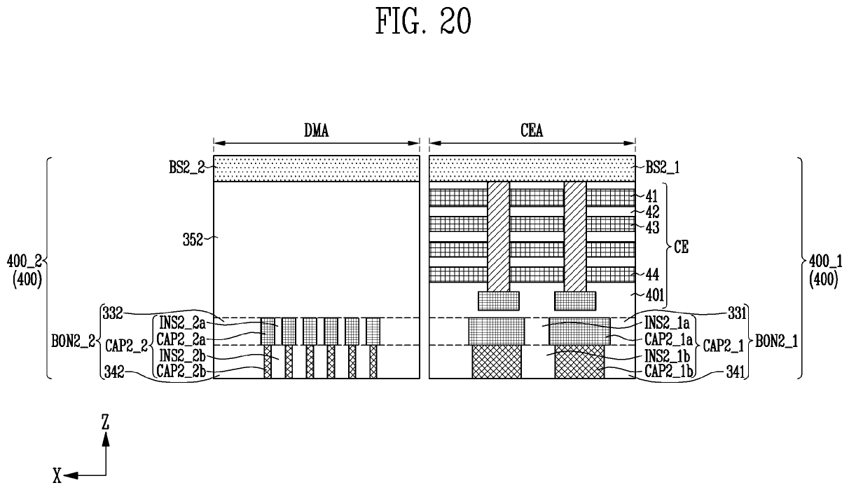

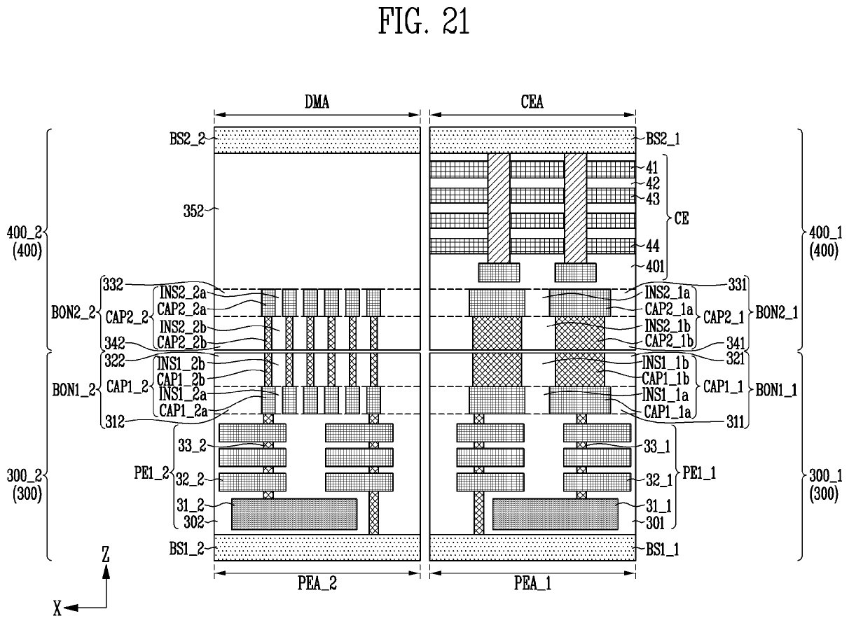

FIGS. 20 and 21 are diagrams illustrating a method of bonding the lower structure 300 and the upper structure 400 to each other according to an embodiment of the present disclosure.

Referring to FIGS. 20 and 21, the upper structure 400 may be disposed such that the bottom surface thereof faces upwards, thus allowing the upper bonding layer BON2 of the upper structure 400 and the lower bonding layer BON1 of the lower structure 300 to be bonded to each other. Therefore, the upper capacitor structure CAP2_2 of the second upper bonding layer BON2_2 in the dummy area DMA may be coupled to the lower capacitor structure CAP1_2 of the second lower bonding layer BON1_2.

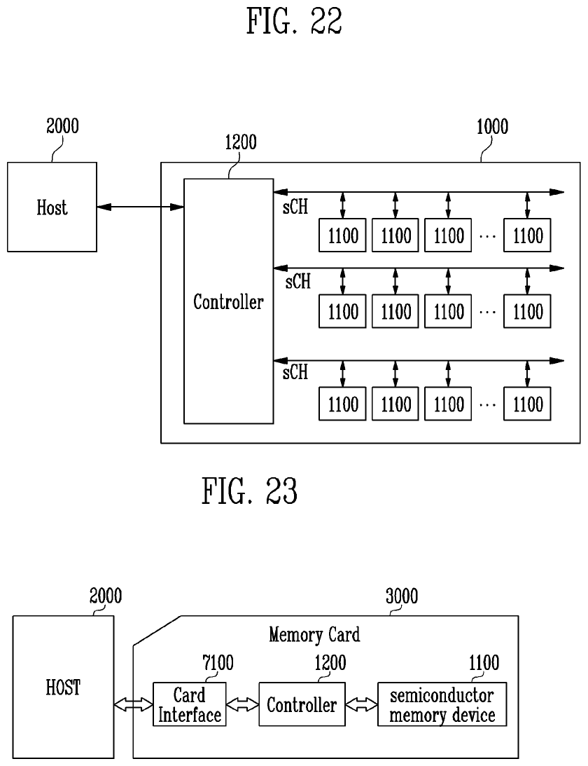

FIG. 22 is a diagram illustrating an embodiment of a memory system including a semiconductor memory device according to an embodiment of the present disclosure.

Referring to FIG. 22, a memory system 1000 may include a plurality of semiconductor memory devices 1100 which store data, and a controller 1200, which performs communication between the semiconductor memory devices 1100 and a host 2000.

Each of the semiconductor memory devices 1100 may be a semiconductor memory device, described in the foregoing embodiments.

The semiconductor memory devices 1100 may be coupled to the controller 1200 through a plurality of system channels sCH. For example, the plurality of semiconductor memory devices 1100 may be coupled to one system channel sCH, and a plurality of system channels sCH may be coupled to the controller 1200.

The controller 1200 may perform communications between the host 2000 and the semiconductor memory devices 1100. The controller 1200 may control the semiconductor memory devices 1100 in response to a request from the host 2000 or may perform a background operation for improving the performance of the memory system 1000 regardless of a request from the host 2000.

The host 2000 may generate requests for various operations and may output the generated requests to the memory system 1000. For example, the requests may include a program request for controlling a program operation, a read request for controlling a read operation, an erase request for controlling an erase operation, etc. The host 2000 may communicate with the memory system 1000 through various interfaces, such as peripheral component interconnect express (PCIe), advanced technology attachment (ATA), serial ATA (SATA), parallel ATA (PATA), serial attached SCSI (SAS), non-volatile memory express (NVMe), universal serial bus (USB), multi-media card (MMC), enhanced small disk interface (ESDI), or integrated drive electronics (IDE).

FIG. 23 is a diagram illustrating an embodiment of a memory system including a semiconductor memory device according to an embodiment of the present disclosure.

Referring to FIG. 23, the memory system may be implemented as a memory card 3000. The memory card 3000 may include a semiconductor memory device 1100, a controller 1200, and a card interface 7100.

The controller 1200 may control data exchange between the semiconductor memory device 1100 and the card interface 7100. In an embodiment, the card interface 7100 may be, but is not limited to, a secure digital (SD) card interface or a multi-media card (MMC) interface.

The card interface 7100 may interface data exchange between a host 2000 and the controller 1200 according to the protocol of the host 2000. In an embodiment, the card interface 7100 may support a universal serial bus (USB) protocol and an interchip (IC)-USB protocol. Here, the card interface 7100 may refer to hardware capable of supporting a protocol which is used by the host 2000, software installed in the hardware, or a signal transmission method.

When the memory card 3000 is coupled to a host interface of the host 2000, such as a PC, a tablet PC, a digital camera, a digital audio player, a mobile phone, console video game hardware or a digital set-top box, the host interface may perform communications with the semiconductor memory device 1100 through the card interface 7100 and the controller 1200 under the control of a microprocessor of the host 2000.

The present disclosure may more efficiently utilize the space of a semiconductor memory device and reduce the size of the semiconductor memory device by forming a capacitor in a fine pattern in a dummy area, thus implementing the high integration of the semiconductor memory device and improving the reliability of the semiconductor memory device.

What is claimed is:

1. A semiconductor memory device, comprising:
a first peripheral area and a second peripheral area;
a lower substrate located in the first peripheral area and the second peripheral area;
a peripheral circuit component located on the lower substrate;
a lower bonding layer, including a lower capacitor structure, located on the peripheral circuit component in the second peripheral area;
an upper bonding layer, including an upper capacitor structure, bonded to the lower bonding layer;
a plurality of cells and a dummy insulating layer that are located on the upper bonding layer;
a cell area and a dummy area; and
an upper substrate located in the cell area and the dummy area, the upper substrate being located on the plurality of cells and the dummy insulating layer,
wherein the upper capacitor structure is located in the dummy area and is coupled to the lower capacitor structure.

2. The semiconductor memory device according to claim 1, wherein the plurality of cells comprise a plurality of insulating layers and a plurality of gate layers that are alternately stacked.

3. The semiconductor memory device according to claim 2, wherein the plurality of gate layers include a source selection line, a word line, and a drain selection line,
wherein the source selection line is located in an uppermost portion, among the plurality of gate layers, and
wherein the drain selection line is located in a lowermost portion, among the plurality of gate layers.

4. The semiconductor memory device according to claim 1, wherein the lower capacitor structure comprises:
lower conductive patterns arranged to be parallel to each other; and
lower insulating patterns located between the lower conductive patterns.

5. The semiconductor memory device according to claim 1, wherein the upper capacitor structure comprises:
upper conductive patterns arranged to be parallel to each other; and
upper insulating patterns located between the upper conductive patterns.

6. The semiconductor memory device according to claim 1, wherein the lower conductive patterns vertically penetrate the lower bonding layer.

7. The semiconductor memory device according to claim 1, wherein the upper conductive patterns vertically penetrate the upper bonding layer.

8. The semiconductor memory device according to claim 1,
wherein the lower bonding layer includes a lower bonding structure in the first peripheral area,
wherein the upper bonding layer includes an upper bonding structure in the cell area, and
wherein the lower bonding structure and the upper bonding structure are coupled to each other.

9. A method of manufacturing a semiconductor memory device, comprising:
forming a peripheral circuit component on a lower substrate on which a first peripheral area and a second peripheral area are defined;
forming a lower bonding layer, including a lower capacitor structure, located on the peripheral circuit component in the second peripheral area;
forming a plurality of cells and a dummy insulating layer on an upper substrate on which a cell area and a dummy area are defined, wherein the dummy insulating layer is located in the dummy area and the plurality of cells are located in the cell area;
forming an upper bonding layer, including an upper capacitor structure, on the dummy insulating layer in the dummy area; and
bonding the lower bonding layer and the upper bonding layer to each other such that the lower capacitor structure and the upper capacitor structure are coupled to each other.

10. The method according to claim 9, wherein forming the plurality of cells on the upper substrate comprises:
forming the plurality of cells by alternately stacking a plurality of insulating layers and a plurality of gate layers.

11. The method according to claim 10, wherein forming the plurality of cells on the upper substrate further comprises:
forming a source selection line on the upper substrate;
forming a word line on the source selection line; and
forming a drain selection line on the word line.

12. The method according to claim 9, wherein the lower capacitor structure is formed to vertically penetrate the lower bonding layer.

13. The method according to claim 9, wherein the upper capacitor structure is formed to vertically penetrate the upper bonding layer.

14. The method according to claim 9,
wherein forming the lower bonding layer comprises forming a lower bonding structure on the peripheral circuit component in the first peripheral area,
wherein forming the upper bonding layer comprises forming an upper bonding structure on the plurality of cells in the cell area, and
wherein bonding the lower bonding layer and the upper bonding layer to each other comprises bonding the lower bonding structure and the upper bonding structure to each other so that the lower bonding structure and the upper bonding structure are coupled to each other.
